(19) United States
(12) Patent Application Publication
(10) Pub. No.: US 2026/0150601 A1
(43) Pub. Date: May 28, 2026

(54) Modifying Openings of an Extreme Ultraviolet Masking Layer

(71) Applicant: Applied Materials, Inc., Santa Clara, CA (US)

(72) Inventors: Chen-Chih Hsu, Gloucester, MA (US); Yung-Chen Lin, Westwood, MA (US); Shurong Liang, Lynnfield, MA (US); Steven Sherman, Newton, MA (US)

(73) Assignee: Applied Materials, Inc., Santa Clara, CA (US)

(21) Appl. No.: 19/183,160

(22) Filed: Apr. 18, 2025

Related U.S. Application Data
(60) Provisional application No. 63/725,826, filed on Nov. 27, 2024.

(51) Int. Cl. H01L 21/3065; H01J 37/305; H01L 21/027

(52) U.S. Cl. CPC H10P 50/242; H01J 37/3053; H10P 76/2041; H01J 2237/3341

(57) ABSTRACT

A method of modifying an opening in a masking material layer provided on a substrate to achieve desired critical dimensions may include forming a plurality of openings in the masking material layer, and performing one or more ion processes on the masking material layer to enlarge or reduce one or more dimensions of the plurality of openings. A first ion process of the one or more ion processes may include directionally depositing a material layer on the masking material layer by directing a material beam at a first non-zero angle relative to a normal direction extending from a top surface of the masking material layer. A second ion process of the one or more ion processes may include performing an angled ion etch by delivering an ion beam at a second non-zero angle relative to the normal direction extending from the top surface of the masking material layer.

### CROSS-REFERENCE TO RELATED APPLICATIONS

The present application claims priority to U.S. Provisional Patent Application No. 63/725,826, filed Nov. 27, 2024, and entitled “METHODS FOR RESHAPING EUV MASKING LAYER OPENINGS,” and incorporates its disclosure herein by reference in its entirety.

### FIELD OF THE DISCLOSURE

The present embodiments relate to semiconductor device patterning and, more particularly, to additive and subtractive process flows to reshape openings in patterned extreme ultraviolet (EUV) resist layers.

### BACKGROUND OF THE DISCLOSURE

In the integrated circuit (IC) industry, functional density (i.e., the number of interconnected devices per wafer area) has generally increased while geometry size (i.e., the smallest component that can be created using a fabrication process) has decreased. This scaling down process generally provides benefits by increasing production efficiency and lowering associated costs. However, such scaling down introduces challenges in maintaining process variations at acceptable levels within a wafer, wafer to wafer, and lot to lot.

For example, as process geometries continue to decrease, critical dimensions (CD) of features of one or more layers of a semiconductor device fabricated on a wafer or other semiconductor substrate are becoming continually smaller, and variations in the CD across the wafer are increasing. CD may refer to the smallest dimension of a feature along a given direction, such as an opening/via width or diameter. As CD variation increases, variation of performance characteristics of devices of the wafer also increases, which can lead to poor device performance and low yield.

Therefore, there is an ongoing need to improve the local CD uniformity, CD uniformity across a given wafer, and CD consistency from wafer to wafer.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

One method includes providing a plurality of openings through a masking material layer, wherein the masking material layer is formed over a stack of layers, and performing one or more ion processes on the masking material layer to modify one or more dimensions of the plurality of openings. A first ion process of the one or more ion processes may include directionally depositing a material layer on the masking material layer by directing a material beam at a first non-zero angle relative to a normal direction extending from a top surface of the masking material layer. A second ion process of the one or more ion processes may include performing an angled ion etch by delivering an ion beam at a second non-zero angle relative to the normal direction extending from the top surface of the masking material layer.

Another method of modifying a plurality of openings of a resist includes providing a plurality of openings in the resist, and performing one or more ion processes on the resist to enlarge or reduce one or more dimensions of the plurality of openings. A first ion process of the one or more ion processes may include directionally depositing a material layer on the resist by directing a material beam at a first non-zero angle relative to a normal direction extending from a top surface of the resist. A second ion process of the one or more ion processes may include performing an angled ion etch by delivering an ion beam at a second non-zero angle relative to the normal direction extending from the top surface of the resist.

A processing apparatus may include a chamber operable to contain a plasma within a chamber volume, and a plate assembly proximate the chamber, wherein ions are extracted through a plurality of apertures of the plate assembly and delivered to a semiconductor device as one or more ion processes to enlarge or reduce one or more dimensions of a plurality of openings of a masking material layer formed over a stack of layers. A first ion process of the one or more ion processes may include directionally depositing a material layer on the resist by directing a material beam at a first non-zero angle relative to a normal direction extending from a top surface of the resist. A second ion process of the one or more ion processes may include performing an angled ion etch by delivering an ion beam at a second non-zero angle relative to the normal direction extending from the top surface of the resist.

### BRIEF DESCRIPTION OF THE DRAWINGS

The accompanying drawings illustrate exemplary approaches of the disclosure, including the practical application of the principles thereof, as follows:

FIG. 1A is a top view of a device including a plurality of openings formed through an extreme ultraviolet (EUV) resist, according to embodiments of the present disclosure;

FIG. 1B is a side cross-sectional view, along cutline A-A′, of the device of FIG. 1A, according to embodiments of the present disclosure;

FIG. 2A is a top view of the device during a first ion process, according to embodiments of the present disclosure;

FIG. 2B is a side cross-sectional view of the device of FIG. 2A, according to embodiments of the present disclosure;

FIG. 3A is a top view of the device following the first ion process, according to embodiments of the present disclosure;

FIG. 3B is a side cross-sectional view of the device of FIG. 3A, according to embodiments of the present disclosure;

FIG. 4A is a top view of a device including a plurality of openings formed through an extreme ultraviolet (EUV) resist, according to embodiments of the present disclosure;

FIG. 4B is a side cross-sectional view, along cutline A-A′, of the device of FIG. 4A, according to embodiments of the present disclosure;

FIG. 4C is a side cross-sectional view, along cutline B-B′, of the device of FIG. 4A, according to embodiments of the present disclosure;

FIG. 5A is a top view of the device during a first ion process, according to embodiments of the present disclosure;

FIG. 5B is a side cross-sectional view of the device of FIG. 5A, according to embodiments of the present disclosure;

FIG. 5C is a top view of the device following the first ion process, according to embodiments of the present disclosure;

FIG. 5D is a side cross-sectional view of the device of FIG. 5C, according to embodiments of the present disclosure;

FIG. 6A is a top view of the device during a second ion process, according to embodiments of the present disclosure;

FIG. 6B is a side cross-sectional view, along cutline B-B′, of the device of FIG. 6A, according to embodiments of the present disclosure;

FIG. 7A is a top view of the device following the second ion process, according to embodiments of the present disclosure;

FIG. 7B is a side cross-sectional view, along cutline A-A′, of the device of FIG. 7A, according to embodiments of the present disclosure;

FIG. 7C is a side cross-sectional view, along cutline B-B′, of the device of FIG. 7A, according to embodiments of the present disclosure;

FIG. 8A is a top view of the device during an ion process, according to embodiments of the present disclosure;

FIG. 8B is a top view of the device following the ion process, according to embodiments of the present disclosure;

FIG. 9A is a top view of a device following an ion process, according to embodiments of the present disclosure;

FIG. 9B is a side cross-sectional view, along cutline B-B′, of the device of FIG. 9A, according to embodiments of the present disclosure;

FIG. 10 shows a semiconductor processing apparatus according to embodiments of the disclosure;

FIG. 11A depicts a system according to embodiments of the disclosure; and

FIG. 11B depicts a plan view of an apparatus of the system of FIG. 11A according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, device, and systems in accordance with the present disclosure will now be described more fully hereinafter with reference to the accompanying drawings, where various embodiments are shown. The methods and systems may be embodied in many different forms and are not to be construed as being limited to the embodiments set forth herein. Instead, these embodiments are provided so the disclosure will be thorough and complete, and will fully convey the scope of the methods to those skilled in the art.

Embodiments herein describe adjustments to the CD of a via/hole/opening of an EUV resist achieved using directional angled deposition and/or etching. These modifications can be made to the EUV photoresist post-EUV lithography, both to reshape the resist beyond the bounds of what's possible with EUV lithography (or alternately enabling lower EUV exposure doses or performing fewer passes of EUV lithography), and to increase the thickness of the EUV resist in some cases to increase the ability of the EUV resist to withstand etching during pattern transfer. This can enable etching thicker hard mask or device layers under the EUV resist, and/or can enable etching materials where there is lower selectivity in the etch, so the EUV resist is etched at a higher rate than desirable compared to the material being etched. Furthermore, in some embodiments, the directional angled deposition and/or etching of the EUV resist can further act to reduce roughness in the patterned EUV resist within and/or around the openings and therefore decrease roughness and related defectivity in the device layers etched using the patterned EUV resist.

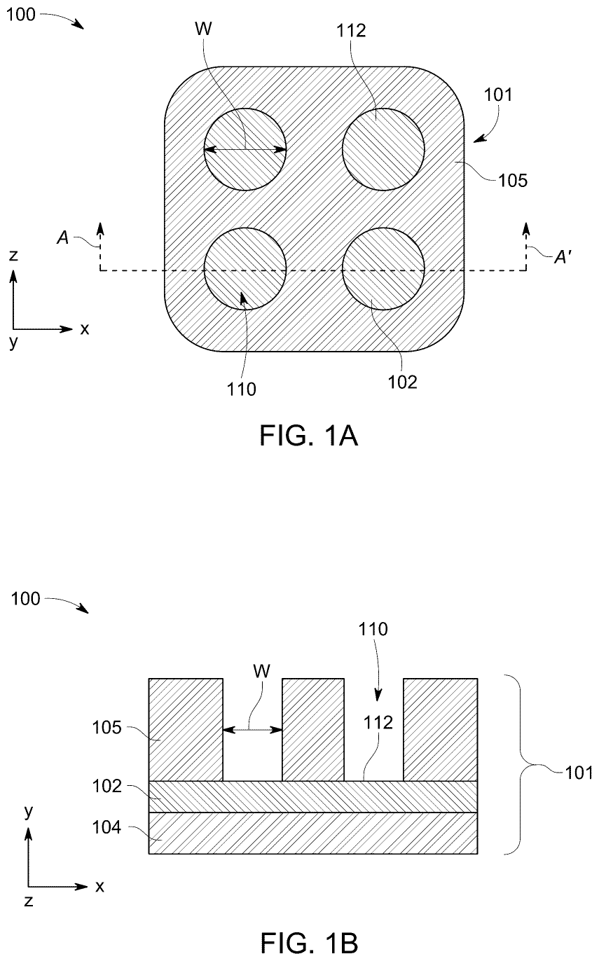

FIG. 1A is a simplified top view, and FIG. 1B is a cross-sectional view along cutline A-A′ of FIG. 1A, of a portion of a semiconductor device (hereinafter “device”) 100, according to one or more embodiments of the disclosure. The device 100 may include a device stack or structure 101 including a first hardmask layer 102 formed over a second hardmask layer 104, and a masking material layer (e.g., patterned EUV resist layer) 105 formed over the first hardmask layer 102.

In various embodiments, the first and second hardmask layers 102, 104 may be silicon oxide (SiO_{X}), silicon carbide (SiC), silicon nitride (SiN), or carbon-based materials, while the resist layer 105 may be an EUV or a deep ultraviolet (DUV) photoresist, such as chemically amplified resist (CAR) or metal oxide resist (MOR). One or more additional materials (not shown) deposited onto the EUV or DUV resist may be SiOx, SiN, carbon-based materials, etc.

As further shown, the device 100 may include a plurality of openings (e.g., vias) 110 formed through the masking material layer 105. The openings 110 extend to an upper surface 112 of the first hardmask layer 102. In the embodiment shown, each of the openings 110 may have a circular profile defining a width (e.g., diameter) ‘W’. The plurality of openings 110 may be formed as a grid or array of features across the device 100. Although only four (4) openings 110 are shown for the sake of simplicity, it will be appreciated that many more openings 110 may be formed across the device 100.

When the masking material layer 105 is patterned, the openings 110 in the masking material layer 105 are ideally formed with a desired shape having desired dimensions, often referred to as “critical dimensions” (CDs), for transferring a desired etch pattern to a substrate. However, due to manufacturing constraints, it can be difficult or impossible to produce patterned masking material layers with openings having certain shapes with nanometer-scale dimensions with high reliability and precision, resulting in undesired CD variation. As used herein, the term “nanometer-scale” shall be defined herein to mean less than 1000 nanometers.

The embodiments of the present disclosure seek to address the challenges associated with producing openings having precise, nanometer-scale dimensions by using directional deposition and direction etch processes to modify resist openings formed using lithographic processes. These two processes, both individually and taken together, can act to modify the openings, while also reducing CD variability of the openings 110.

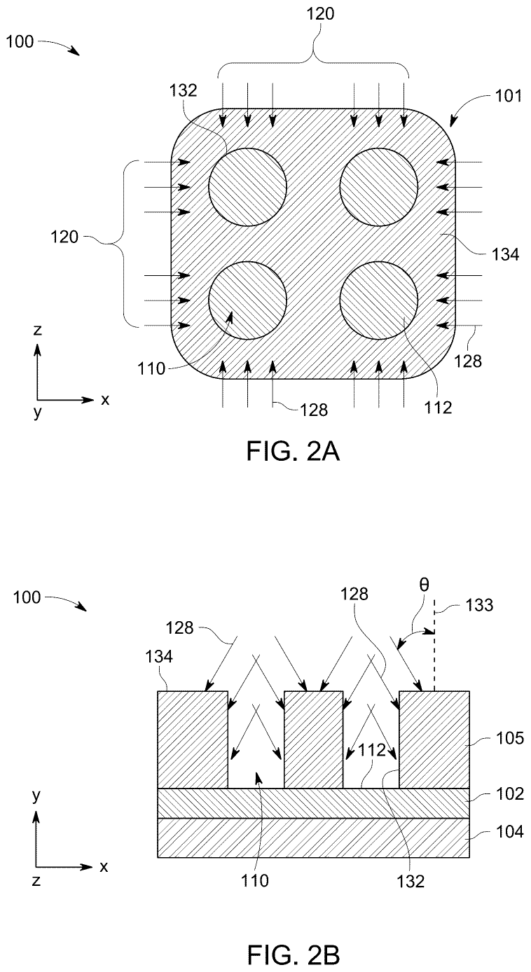

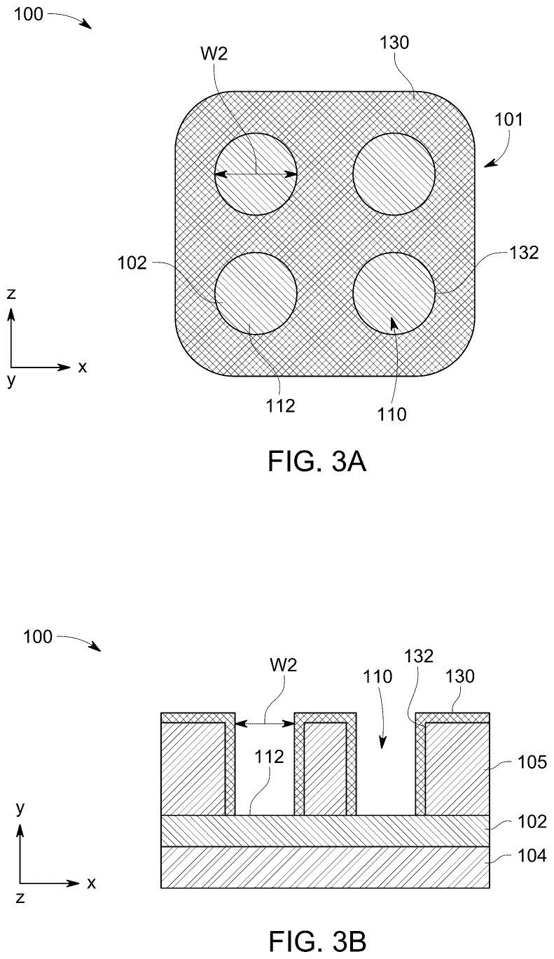

FIG. 2A is a simplified top view, and FIG. 2B is a simplified cross-sectional side view, of the device 100 during a first ion process 120. FIG. 3A is a simplified top view, and FIG. 3B is a simplified cross-sectional side view, of the device 100 after the first ion process 120. In this embodiment, the first ion process 120 may be a directional deposition process performed on the masking material layer 105, wherein a material beam 128 is projected onto the masking material layer 105 at an angle θ with respect to a line 133 (FIG. 2B) normal to a plane defined by an upper surface 134 of the masking material layer 105 to deposit a material layer 130 (FIGS. 3A, 3B) thereon. Following the formation of the material layer 130, the openings may have a width or diameter of ‘W’, as shown in FIGS. 3A-3B , which is less than W, as shown in FIGS. 1A-1B .

In some embodiments, the material beam 128 can comprise ions and/or radicals that are emitted from an ion source or are generated using a plasma-enhanced chemical vapor deposition (PECVD) process in which electrodes are positioned relative to the device 100 such that material is deposited at a desired angle. In various embodiments, the deposited material may be a film layer, such as a carbon-based film or a silicon-based film with various precursors. For example, the film layer may be carbon with an CO, COS or CH4 precursor, aSi, SiOx with a SiCl4 or O2 precursor, SiN with a SiCl4 or N2 precursor, or boron (BCl3). In other embodiments, a fluorine-based chemistry may be used for reshaping the openings.

In some embodiments, the angle at which the material beam 128 is projected onto the masking material layer 105 is selected such that the material layer 130 is at least predominantly deposited on a sidewall(s) 132 of the openings 110 and with little to no material deposited on the upper surface 112 of the first hardmask 102 within the openings 110. The material layer 130 may be further deposited on the upper surface 134 of the masking material layer 105. In this regard, in some embodiments, the angle θ is selected based on the dimensions of the openings 110. For example, in configurations in which each of the openings 110 has an aspect ratio of its width with respect to its depth of about 0.6:1, an angle θ of about 10-30° can be selected such that the material beam 128 does not directly deposit material on the upper surface 112 of the first hardmask 102 within the openings 110. In other embodiments, in which the openings have a shallower configuration (e.g., each opening having an aspect ratio of its width to its depth of about 5:1), the angle θ can be selected to be about 60-70° such that material from the material beam 128 is predominantly deposited on the sidewalls of the openings 110. Thus, for many common configurations of openings 110, the angle θ can be selected to have a value of between about 10° and about 70° with respect to the line 133 normal to the upper surface 134 of the masking material layer 105. Those having ordinary skill in the art will recognize, however, that other values for the angle θ can be selected to correspond to the dimensions of the openings 110.

In some embodiments, the material beam 128 can be emitted from a plurality of separate PECVD sources to ensure that material is deposited substantially uniformly about the sidewall(s) of each of the openings 110. Alternatively, or in addition, the material beam 128 can be sequentially emitted from one or more PECVD source, wherein the substrate and/or the PECVD source(s) may be repositioned for a plurality of deposition steps. For example, the device 100 may be rotated about a central axis perpendicular to the surface of the masking material layer 105 (e.g., in increments of 15 degrees, 45 degrees, 90 degrees) after each of the plurality of deposition steps. Alternatively, the one or more PECVD sources can be rotated relative to the masking material layer 105 about the central axis perpendicular to the surface of the masking material layer 105 (e.g., in increments of 15 degrees, 45 degrees, 90 degrees) after each of the plurality of deposition steps. In any configuration, the repositioning of the substrate and/or the PECVD source(s) can ensure that material is deposited substantially uniformly on the sidewall(s) of the openings 110. In addition, in some embodiments, the directional deposition process can further act to increase the height of the masking material layer 105.

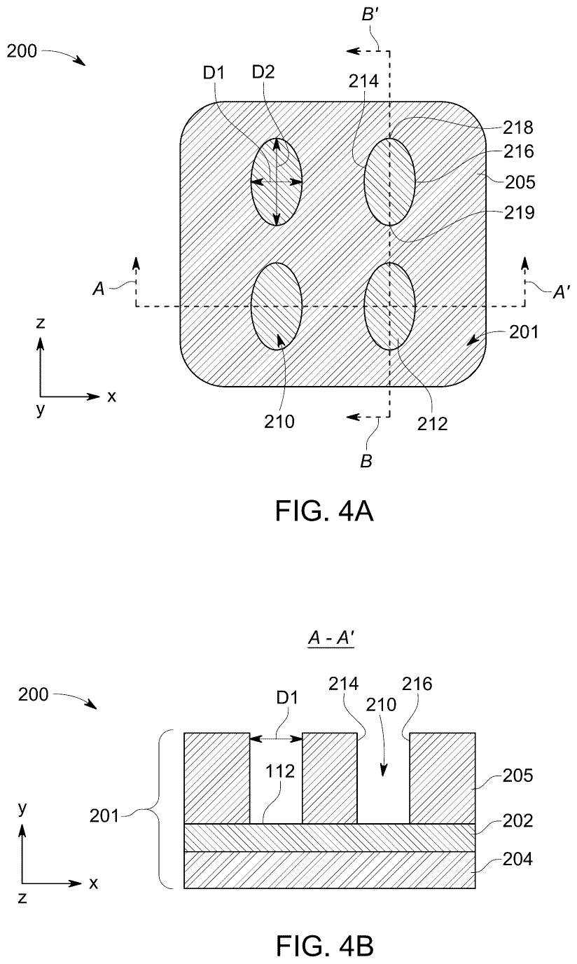

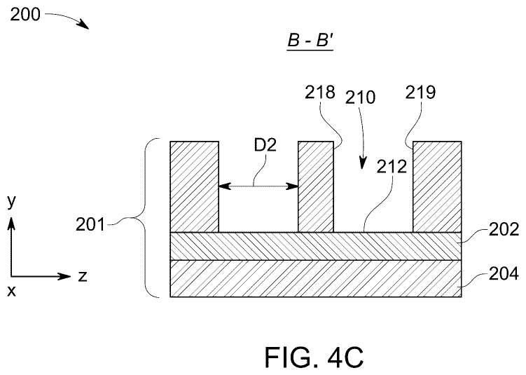

FIG. 4A is a simplified top view, FIG. 4B is a cross-sectional side view along cutline A-A′ of FIG. 4A, and FIG. 4C is a cross-sectional side view along cutline B-B′ of FIG. 4A of a portion of a semiconductor device (hereinafter “device”) 200, according to one or more embodiments of the disclosure. The device 200 may share many of the same features as device 100 and, as such, only certain aspects of the device 200 will hereinafter be described for the sake of brevity.

The device 200 may include a device stack or structure 201 including a first hardmask layer 202 formed over a second hardmask layer 204, and a masking material layer (e.g., EUV resist layer) 205 formed over the first hardmask layer 202. As further shown, the device 200 may include a plurality of openings (e.g., vias) 210 formed through the masking material layer 205. The openings 210 extend to an upper surface 212 of the first hardmask layer 202. In the embodiment shown, each of the openings 210 may have an oval or elliptical profile defined by a first side 214 opposite a second side 216, and a first end 218 opposite a second end 219. Dimension ‘D1’ extends in the x-direction, between the first side 214 and the second side 216, and dimension ‘D2’ extends in the z-direction, between the first end 218 and the second end 219. In this embodiment, D2>D1. In other embodiments, each of the openings 210 may be substantially round/circular.

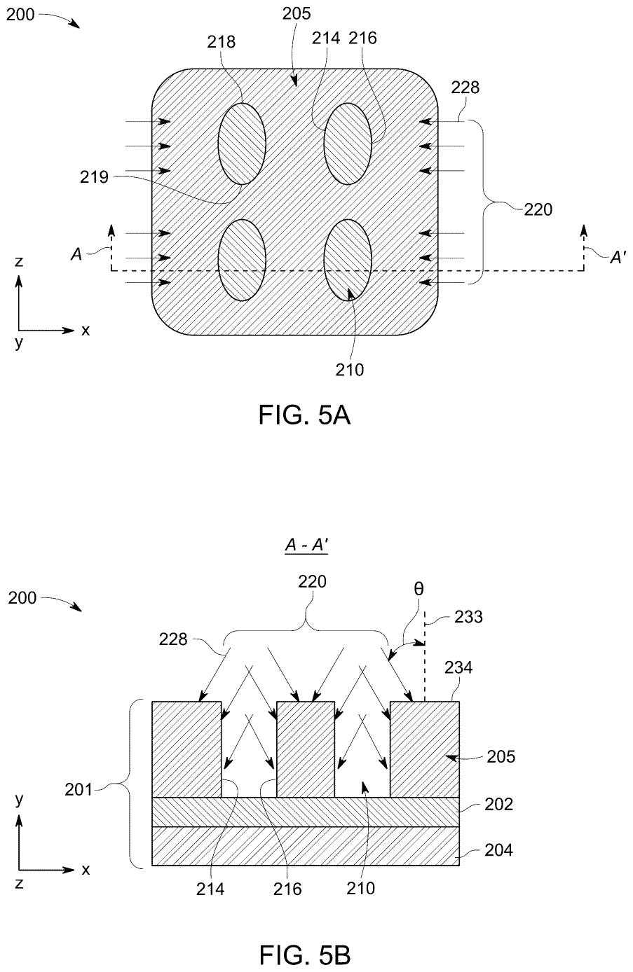

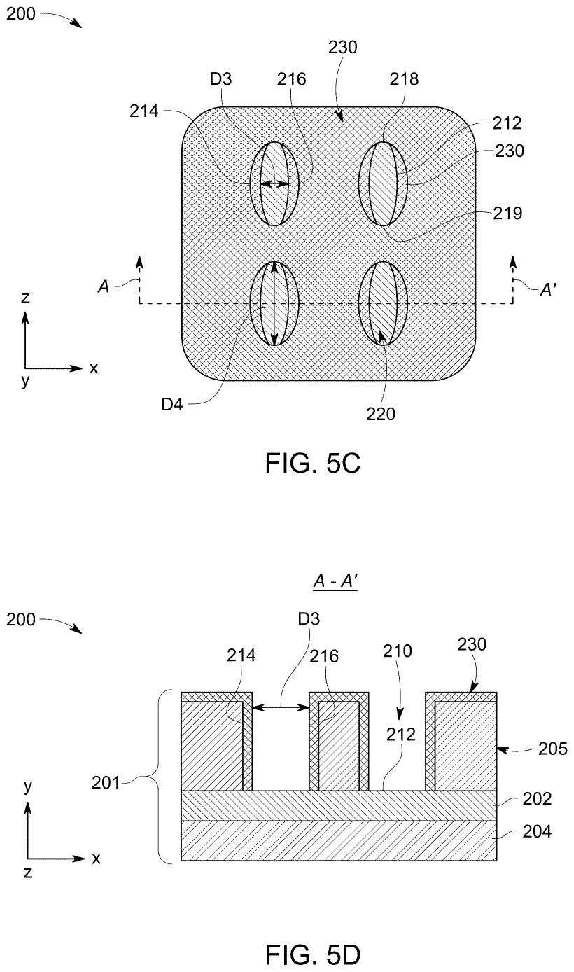

FIG. 5A is a simplified top view, and FIG. 5B is a simplified cross-sectional side view, of the device 200 during a first ion process 220. In this embodiment, the first ion process 220 may be a directional deposition process performed on the masking material layer 205, wherein a material beam 228 is projected onto the masking material layer 205 at an angle θ with respect to a line 233 (FIG. 5B) normal to a plane defined by an upper surface 234 of the masking material layer 205. The material beam 228 may further impact the sidewalls of the openings 210, primarily the first and second sides 214, 216. Due to the angle of the first ion process 220, the material beam 228 generally does not impact the first or second ends 218, 219 of each opening 210.

In some embodiments, the material beam 228 may be ions and/or radicals that are emitted from an ion source or are generated using a plasma-enhanced chemical vapor deposition (PECVD) process in which electrodes are positioned relative to the device 200 such that material is deposited at a desired angle (θ). In some embodiments, the angle at which the material beam 228 is projected onto the masking material layer 205 is between about 10° and about 70° with respect to the line 233 normal to the upper surface 234. Those having ordinary skill in the art will recognize, however, that other values for the angle θ can be selected to correspond to the dimensions of the openings 210.

As shown in FIG. 5C and FIG. 5D, a material layer 230 may be formed along exposed surfaces of the masking material layer 205 as a result of the material beam 228 being directed to the masking material layer 205. More specifically, the material layer 230 may be formed along the upper surface 234 of the masking material layer 205 and along the first and second sides 214, 216 of the openings 210. The material layer 230 is generally not formed along the first and second ends 218, 219 of the openings 210, or along the upper surface 212 of the first hardmask layer 202. As a result, following the formation of the material layer 230, the openings 210 may have a dimension ‘D3’ in the x-direction, which is less than D2 (FIGS. 4A, 4B). However, a dimension ‘D4’ in the z-direction may be substantially the same as D1 (FIGS. 4A, 4C) following the deposition.

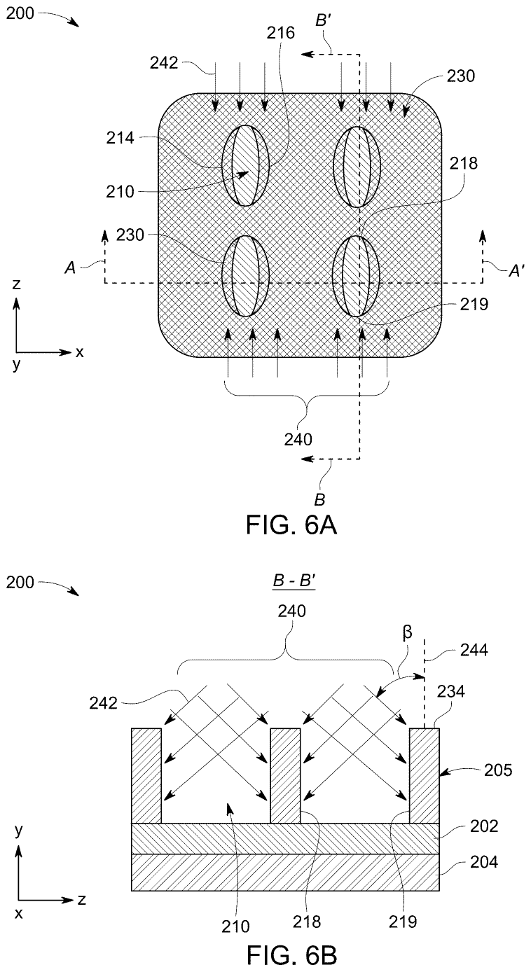

FIG. 6A is a simplified top view, and FIG. 6B is a simplified cross-sectional side view, of the device 200 during a second ion process 240. In this embodiment, the second ion process 240 may be a directional removal process (e.g., a plasma etch process or reactive ion etch) performed on the masking material layer 205 and the material layer 230, wherein one or more ion beams 242 are delivered to the masking material layer 205 at an angle β with respect to a line 244 (FIG. 6B) normal to the upper surface 234 of the masking material layer 205 to remove a portion of masking material layer 205 within the openings 210. As shown, the ion beam 242 is directed in the y-direction and the z-direction to primarily impact the first and second ends 218, 219 of each opening 210, without significantly impacting the first and second sides 214, 216 of each opening 210. The second ion process 240 may include at least one of the following angled ion etch chemistries: Ar+, N+, He+, H+, O+, CH+, CF+, CxHyF+, CO+, COS+, BCl3+, although the present disclosure is not limited in this regard.

In some embodiments, the angle β at which the ion beam 242 is directed to the masking material layer 205 is selected such that etch predominantly impacts the sidewalls of the openings 210 without impacting a bottom of the openings 210. In some embodiments, the angle β can be selected to have a value of between about 10° and about 70° with respect to the line 233 normal to the top surface of the masking material layer 205. Those having ordinary skill in the art will recognize, however, that other values for the angle β can be selected to correspond to the dimensions of the openings 210.

In some embodiments, the ion beam 242 can be sequentially emitted from one or more ion or plasma sources, wherein the substrate and/or the source(s) may be repositioned for a plurality of etch steps. For example, the substrate may be rotated about a central axis perpendicular to the surface of the masking material layer 205 (e.g., in increments of 15 degrees, 45 degrees, 90 degrees, 180 degrees, etc.) after each of the plurality of etch steps. Alternatively, the one or more ion or plasma sources can be rotated relative to the masking material layer 205 about the central axis perpendicular to the surface of the masking material layer 205 (e.g., in increments of 15 degrees, 45 degrees, 90 degrees, 180 degrees) after each of the plurality of etch steps. In addition, in some embodiments, the directional etch process can further act to decrease the height of the masking material layer 205.

In some embodiments, the ion implantation (e.g., ion etch) of the second ion process 240 and the directional deposition processes of the first ion process 220 can be performed sequentially. Alternatively, in other embodiments, the ion implantation and the directional deposition processes can be performed concurrently.

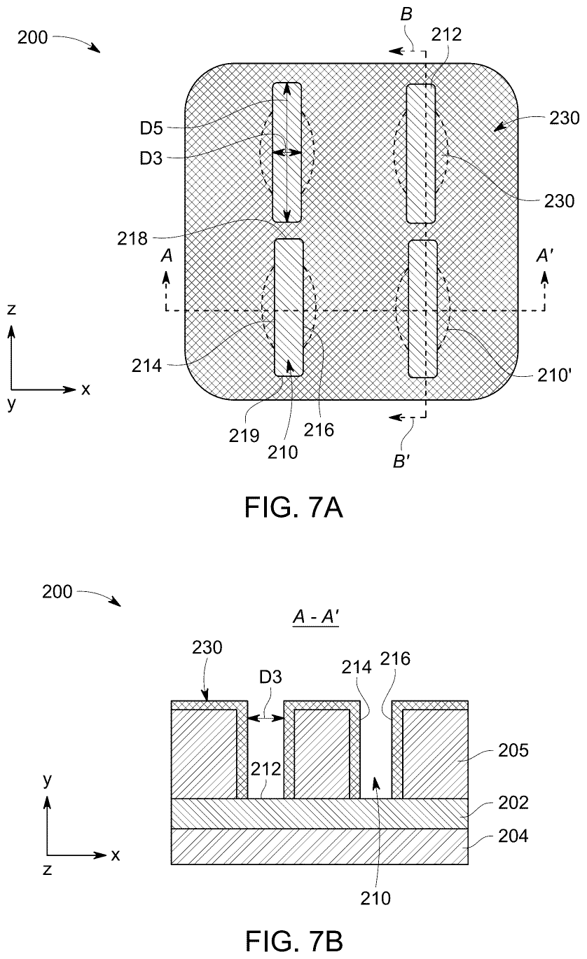

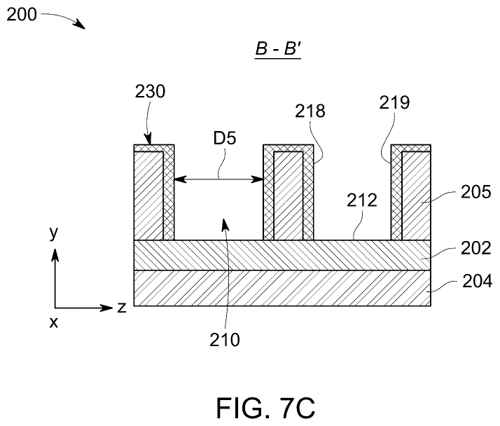

FIGS. 7A-7C demonstrate the device 200 following the first ion process 220 and the second ion process 240. As shown, each of the openings 210 may be reduced in the x-direction as a result of the first ion process 220 and enlarged in the z-direction as a result of the second ion process 240. Stated another way, material is added to the first and second sides 214, 216 of each opening 210 and removed from the first and second ends 218, 220. As such, the openings 210 may have dimension ‘D5’ in the z-direction, which is greater than D1 (FIGS. 4A, 4C), and dimension ‘D3’ in the x-direction, which is less than D2 (FIGS. 4A, 4B).

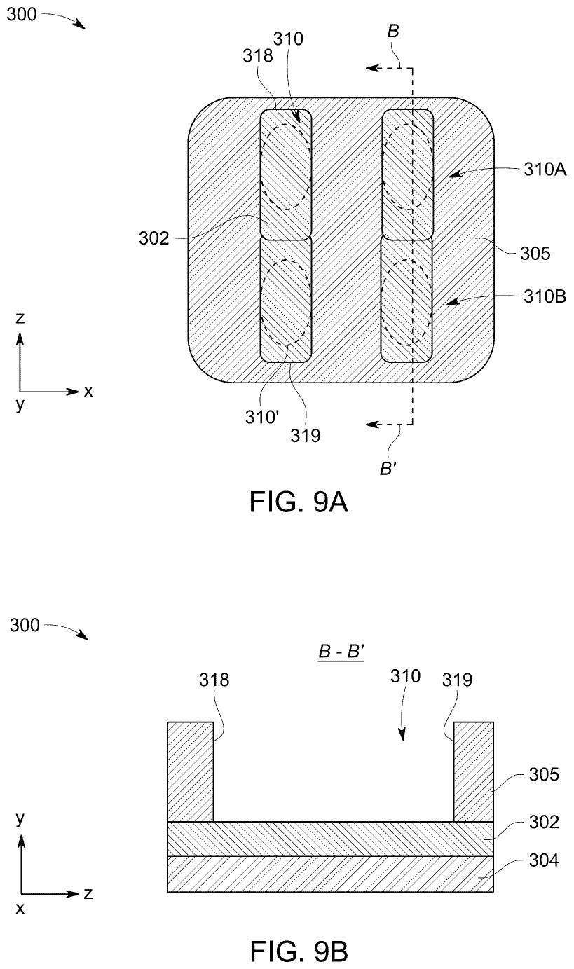

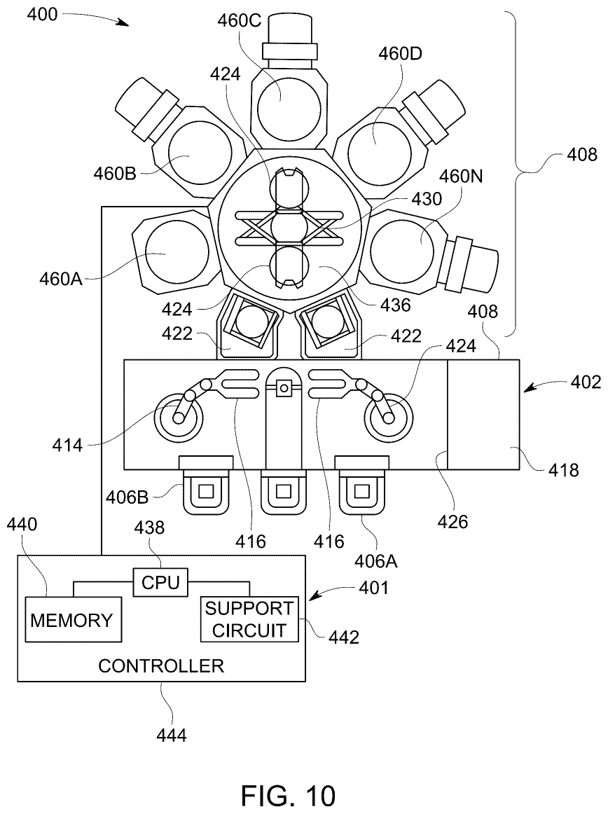

A perimeter 210′ (FIG. 7A), demonstrated by the dashed line, corresponds to each opening prior to the first and second ion processes 220, 240. In the case each of the openings 210 initially has an oval or elliptical profile, the first and second ion processes 220, 220 may result in a rectangular profile of the openings 210 being achieved. In some embodiments, the second ion process 240 may continue until one or more of the openings 310 connect or merge. For example, one or more of the openings 310 may be expanded in the +/−z-directions until joined, as will be described in greater detail herein with respect to FIGS. 9A-9B .

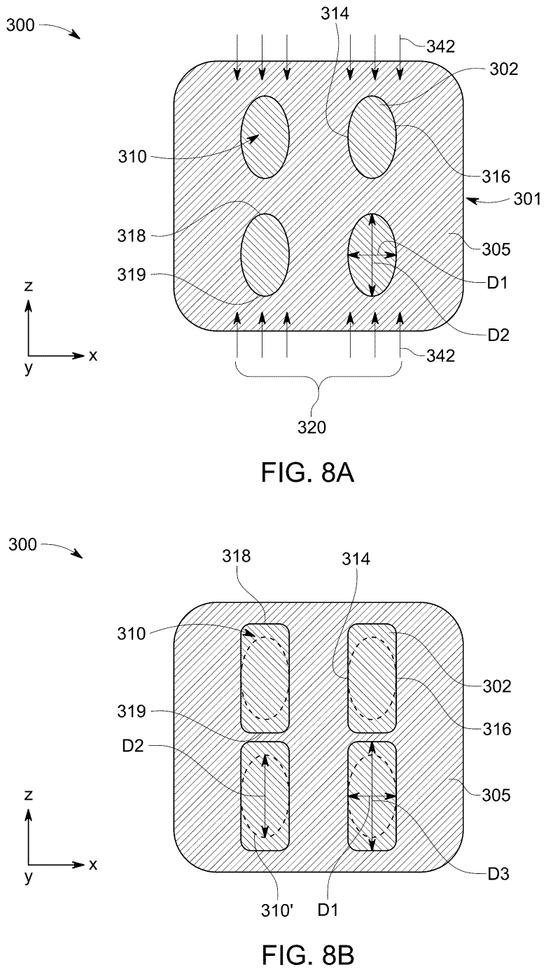

FIG. 8A is a simplified top view of a portion of another semiconductor device (hereinafter “device”) 300 according to one or more embodiments of the disclosure. The device 300 may share many of the same features as devices 100 and 200 described herein and, as such, only certain aspects of the device 300 will hereinafter be described for the sake of brevity.

The device 300 may include a device stack or structure 301 including a first hardmask layer 302 formed over a second hardmask layer (not shown), and a masking material layer (e.g., EUV resist layer) 305 formed over the first hardmask layer 302. As further shown, the device 300 may include a plurality of openings (e.g., vias) 310 formed through the masking material layer 305. The openings 310 extend to an upper surface of the first hardmask layer 302. In the embodiment shown, each of the openings 310 may have an oval or elliptical profile defined by a first side 314 opposite a second side 316, and a first end 318 opposite a second end 319. A first dimension ‘D1’, extending in the x-direction between the first side 314 and the second side 316, is greater than a second dimension ‘D2’, which extends in the z-direction between the first and second ends 318, 319.

As further shown, the device 300 may be subjected to an ion process 320. In this embodiment, the ion process 320 may be a directional removal process (e.g., a plasma etch process or reactive ion etch) performed on the masking material layer 305, wherein one or more ion beams 342 are delivered to the masking material layer 305 at an angle to remove a portion of masking material layer 305 within the openings 310. More specifically, the one or more ion beams 342 may impact the first and second ends 318, 319 of the openings 210, without significantly impacting the first and second sides 314, 316.

As shown in FIG. 8B, each of the openings 310 may be expanded or enlarged in the z-direction as a result of the ion process 320 without being significantly expanded or enlarged in the x-direction. Perimeter 310′, demonstrated by the broken lines, corresponds to each opening prior to the ion process 320. As such, the expanded openings 310 may have a third dimension ‘D3’, extending in the z-direction, which is greater than D2. However, a width (i.e., D1) of each opening 310 will not significantly change as a result of the ion process 320.

In the embodiment shown in FIGS. 9A-9B , the ion process 320 may continue until one or more of the openings 310 connect or join. For example, a first set of openings 310A and/or a second set of openings 310B may be expanded in the +/−z-directions until merged. As a result, the openings 310 transform to take on an expanded trench or line configuration. It will be appreciated that an etch chemistry and/or etching duration may be optimized to join together the first and second sets of openings 310A, 310B. The ion process 320 may include at least one of the following angled ion etch chemistries: Ar+, N+, He+, H+, O+, CH+, CF+, CxHyF+, CO+, COS+, BCl3+, although the present disclosure is not limited in this regard.

FIG. 10 is a schematic top plan view of an exemplary cluster processing system 400 that includes one or more of the processing chambers operable to form the devices 100, 200, and 300 described herein. In one embodiment, the cluster processing system 400 may be an integrated processing system commercially available from Applied Materials, Inc., located in Santa Clara, CA. It is contemplated that other processing systems (including those from other manufacturers) may be adapted to benefit from the disclosure.

The cluster processing system 400 may include a vacuum-tight processing platform 404, a factory interface 402, and a system controller 444. The platform 404 includes a plurality of processing chambers 460A-460N and at least one load-lock chamber 422 that is coupled to a vacuum substrate transfer chamber 436. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). The factory interface robot 414 having a blade 416 disposed on one end of the robot 414 is configured to transfer the substrate from the factory interface 402 to the processing platform 404 for processing through the load lock chambers 422. Optionally, one or more metrology stations 418 may be connected to a terminal 426 of the factory interface 402 to facilitate measurement of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

In one embodiment of the cluster processing system 400, the cluster processing system 400 may include one or more processing chambers 460A-460N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, implant chamber, lithographic exposure chamber, or other similar type of semiconductor processing chambers. More specifically, etch chamber 460A may include an etch tool operable to perform an angled etch using a reactive plasma beam delivered at a non-zero angle, as described herein with respect to devices 200 and 300. Meanwhile, deposition chamber 460B may include a deposition tool operable to perform an angled material deposition at a non-zero angle to modify portions of openings, as described herein with respect to devices 100 and 200. In other embodiments, the etch and deposition processes can be performed in the same chamber, such as an angled plasma beam chamber, e.g., by changing the chemistry being used in the chamber. The etch and deposition processes may occur sequentially, but they may also occur simultaneously, by running both the etch and the bombardment chemistries at the same time.

The transfer chamber 436 has a vacuum robot 430 disposed therein. The vacuum robot 430 has a blade capable of transferring substrates 424 among the load lock chambers 422, the metrology system 410 and the processing chambers 460A-460N.

The system controller 444 is coupled to the cluster processing system 400. The system controller 444, which may include the computing device 401 or be included within the computing device 401, controls the operation of the cluster processing system 400 using a direct control of the processing chambers 460A-460N of the cluster processing system 400. Alternatively, the system controller 444 may control the computers (or controllers) associated with the processing chambers 460A-460N and the cluster processing system 400. In operation, the system controller 444 also enables data collection and feedback from the respective chambers to optimize performance of the cluster processing system 400.

The system controller 444, much like the computing device 401 described above, generally includes a central processing unit (CPU) 438, a memory 440, and support circuits 442. The CPU 438 may be one of any form of a general-purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (controller) 444. The software routines may also be stored and/or executed by a second controller (not shown) that is located remotely from the cluster processing system 400.

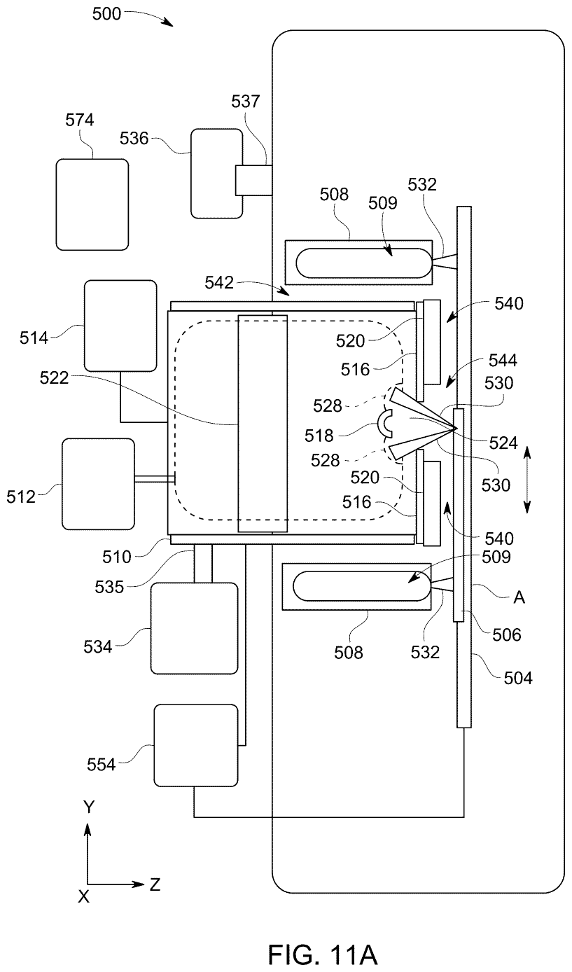

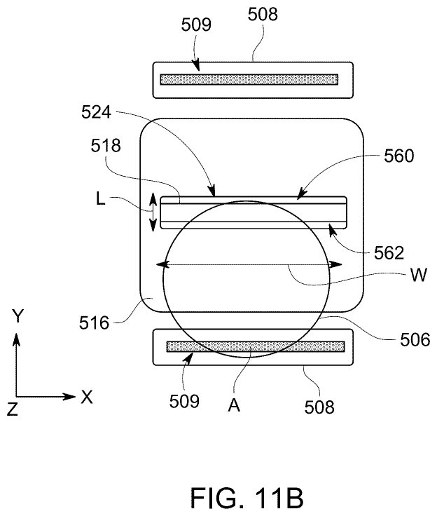

FIG. 11A is a schematic cross-sectional view of a processing apparatus 500 including an exemplary plasma processing chamber suitable for performing a patterning process. The plasma processing chamber may correspond to one of the processing chambers 460A-460N of the cluster processing system 400 described above. It is contemplated that other process chambers, including those from other manufactures, may be adapted to practice embodiments of the disclosure. It will be further contemplated that the components of the processing apparatus 500 are not necessarily to scale. The drawings are merely representations, not intended to portray specific parameters of the disclosure.

The apparatus 500 may include various components that operate together as an apparatus providing novel and improved etching and/or material deposition on a substrate 506. As illustrated, the apparatus 500 may include a process chamber 502 and a substrate stage 504 disposed within the process chamber 502.

The apparatus 500 further includes at least one reactive gas source, shown as the reactive gas source 508. The reactive gas source 508 may have a reactive gas outlet 509 disposed within the process chamber 502. The reactive gas source 508 may be employed to deliver reactive gas 532 to the substrate 506 when the substrate 506 is adjacent the reactive gas source 508. In various embodiments, the reactive gas 532 may be capable of reacting with material of the substrate 506, wherein a first product layer comprising the reactive gas 532 and material from the substrate 506 is formed on an outer surface of the substrate. For example, in one particular non-limiting embodiment, the reactive gas 532 may comprise chlorine or a chlorine-containing material, while the substrate 506 is silicon. The reactive gas 532 may be delivered as a neutral species, may be delivered as a radical, may be delivered as an ion or may be delivered as a combination of neutrals, radicals and ions in some embodiments. A product layer may form as layer composed of a monolayer of chlorine species bonded to an underlayer of silicon species. The embodiments are not limited in this context.

The apparatus 500 further includes a plasma chamber 510. The plasma chamber 510 may include an extraction plate 516. As illustrated in FIG. 11A, the extraction plate 516 partially separates the plasma chamber 510 from the process chamber 502. The extraction plate 516 also includes an aperture 524 providing gaseous communication between the plasma chamber 510 and the process chamber 502, where the aperture 524 acts as an extraction aperture. In this manner, the plasma chamber 510 may be coupled to the process chamber 502. The aperture 524 may be an elongated aperture that extends along a first direction, such as parallel to the X-axis, as shown in FIG. 11B. For example, the aperture 524 may have a width ‘W’ ranging between 100 mm and 500 mm in some embodiments and a length ‘L’ ranging between 3 mm and 30 mm in some embodiments. The embodiments are not limited in this context. This elongated configuration of aperture 524 allows the extraction of an ion beam (“plasma beam”) as a ribbon beam, meaning an ion beam having a cross-section where the beam width is greater than a beam length.

As further shown in FIG. 11A, the apparatus 500 may include an inert gas source 512 coupled to the plasma chamber 510 to provide inert gas such as Ar, He, Ne, Kr, and so forth. The apparatus 500 may further include additional components such as a power generator 514, where the components together form a plasma source to generate a plasma 522.

The plasma 522 may be generated by coupling electric power from a power generator 514 to the rarefied gas provided by inert gas source 512 in the plasma chamber 510 through an adequate plasma exciter (not shown). As used herein, the generic term “plasma source” may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art. Therefore, depending on the nature of the plasma source, the power generator 514 may be an rf generator, a dc power supply, or a microwave generator, while plasma exciter may include rf antenna, ferrite coupler, plates, heated/cold cathodes, helicon antenna, or microwave launchers. The apparatus 500 further may include a bias power supply 554 connected to the plasma chamber 510 or to a substrate stage 504, or to the plasma chamber 510 and substrate stage 504.

Although not explicitly shown, the plasma chamber 510 may be electrically isolated from the process chamber 502. Extraction of a plasma beam 530 comprising positive ions through the aperture 524 may accomplished by either elevating the plasma chamber 510 at positive potential and grounding the substrate stage 504 directly or via grounding the process chamber 502, or by grounding the plasma chamber 510 and applying negative potential on the substrate stage 504. The bias power supply 554 may operate in either a dc mode or pulsed mode having a variable frequency and duty cycle, or an AC mode. The extraction plate 516 may be arranged generally according to known design to extract ions in the plasma beam 530 in a manner that allows control of the ion angular distribution, i.e., the angle of incidence of the plasma beam 530 with respect to a substrate 506 and the angular spread as detailed below.

In some embodiments, just one plasma beam 530 may be extracted through the aperture 524. In other embodiments, a pair of plasma beams may be extracted through the aperture 524. For example, as illustrated in FIG. 11A and FIG. 11B, a beam blocker 518 may be disposed within the plasma chamber 510 and adjacent the aperture 524, where the beam blocker 518 defines a first extraction aperture 560 and second extraction aperture 562. As shown in FIG. 11A, two plasma beams 530 may be extracted from the plasma chamber 510 and directed to the substrate 506.

As further shown in FIG. 11A, the apparatus 500 may include a pumping port 535 coupled to the plasma chamber 510 and a plasma chamber pump 534 connected to the pumping port 535. The plasma chamber pump 534 may be employed, for example, to reduce concentration of certain species within the plasma chamber 510, as discussed below. The apparatus 500 may further include a process chamber pump 536 coupled to the process chamber 502 via a pumping port 537 to evacuate the process chamber 502.

The apparatus 500 may further include a gas flow restrictor disposed between the reactive gas outlet and the extraction aperture, shown as the gas flow restrictor 520. As shown in FIG. 11A, for example, a gas flow restrictor 520 may be disposed on the outside of extraction plate 516 facing the substrate stage 504. The gas flow restrictor may define a differential pumping channel 540 between at least the plasma chamber 510 and substrate stage 504.

In operation, the substrate stage 504 may scan the substrate parallel to the Y-axis with respect to the extraction plate 116. In this manner, different portions of the substrate 506 may be exposed to the reactive gas 532 at different times. For example, the reactive gas outlet 509 may be elongated as shown in FIG. 11B and may have a width along the X-axis similar to the width W of the aperture 524, and a length along the Y-axis of 3 mm, for example. In various embodiments, the reactive gas outlet 509 may be composed of a multitude of small holes distributed over the X and Y dimensions to define an elongated shape as shown by the dashed lines, for uniform gas distribution along the X dimension. Moreover, the distance between the reactive gas source 508 and substrate 506 along the Z-axis may be 5 mm or less in some examples. The embodiments are not limited in this context. In this manner, the reactive gas 532 may be provided as a narrow, elongated stream that covers the substrate 506 in its entirety along the X-axis, while just covering the substrate 506 over several millimeters in the direction parallel to the Y-axis. Accordingly, the entirety of the substrate 506 may be exposed to the reactive gas 532 in a sequential fashion by scanning the substrate along the Y-axis. Likewise, different portions of the substrate 506 may be exposed to the plasma beam(s) 530 at different times.

Additionally, as illustrated in FIG. 11B, a given region, such as a region ‘A’ of the substrate 506, may be exposed to the reactive gas 532 and plasma beam 530 in a sequential fashion. In this manner, in an example of scanning the substrate 506 from bottom to top, a product layer made from the species of the reactive gas 532 and substrate 506 may initially be formed at the region ‘A’. The product layer may be an ALE layer as discussed above where the product layer is a monolayer formed by a self-limiting reaction. The product layer formed in region ‘A’ may be subsequently etched by the plasma beam 530, when the region ‘A’ is scanned upwardly under the plasma beam 530. In this manner, the substrate 506 may be etched in a monolayer-by-monolayer fashion by sequentially scanning the substrate under the reactive gas 532 and plasma beam 530.

In accordance with embodiments of the disclosure, the gas flow restrictor 520 may define a low conductance channel, shown as differential pumping channel 540, between at least the extraction plate 516 and substrate stage 504. As discussed below, the differential pumping channel 540 may establish a large pressure difference between one end of the differential pumping channel 540 and the other end. The reactive gas source 508 is separated from the plasma chamber 510 by a large conductance aperture in direct communication to a pumping source. The pumping source can be the process chamber pump 536 or any other pumping source made to communicate with aperture 542. In accordance with various embodiments, using appropriate design of aperture 542 and differential pumping channel 540 the partial pressure of the reactive gas in these two spatial regions may differ by 2 to 3 orders of magnitude. Using this differential pumping method, the apparatus 500 may, for example, maintain a partial pressure of the reactive gas 532 adjacent the reactive gas outlet 509 of 1E-3 Torr, while having a partial pressure of 1E-6 Torr at the region 544 adjacent the aperture 524, leading to the plasma chamber 510.

A result of this pressure differential is that species of reactive gas 532 may be prevented from backstreaming into the region 544 or into plasma chamber 510, and may be preferentially pumped through the pumping port 537. This may facilitate the ability to control the composition of plasma beam 530, such as reducing or eliminating reactive gas species from the plasma beam 530. In this manner, a more controllable etch process may be realized by maintaining the exposure of substrate 506 to reactive gas 532 separate from the exposure to the plasma beam 530. Additionally, or alternatively, the plasma chamber 510 may be evacuated by the plasma chamber pump 534, further reducing the concentration of species from reactive gas 532 in plasma chamber 510.

In accordance with various embodiments, the substrate stage 504 may be scanned sequentially under the reactive gas source 508 and plasma chamber 510 while the reactive gas source 508 and plasma chamber 510 are maintained in an ON state. In this manner, the apparatus 500 may provide a high throughput ALE process. In particular, a purge cycle may be avoided where the reactive gas 532 would otherwise be purged between exposure to reactive gas and exposure to an etching process (e.g., plasma beam 530) as in known ALE processes. Moreover, in some embodiments, the substrate stage 504 may scan a substrate 506 back and forth (up and down in FIG. 11A) in a continuous fashion for a predetermined number of scan cycles in order to etch a predetermined amount of material from substrate 506. Since the thickness of a given product layer may be readily calculated, the total thickness to be etched may readily be controlled according to the number of scan cycles to be performed.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a plurality of openings through a masking material layer, wherein the masking material layer is formed over a stack of layers; and
performing one or more ion processes on the masking material layer to modify one or more dimensions of the plurality of openings, wherein a first ion process of the one or more ion processes comprises directionally depositing a material layer on the masking material layer by directing a material beam at a first non-zero angle relative to a normal direction extending from a top surface of the masking material layer, and wherein a second ion process of the one or more ion processes comprises performing an angled ion etch by delivering an ion beam at a second non-zero angle relative to the normal direction extending from the top surface of the masking material layer.

2. The method of claim 1, further comprising simultaneously performing the first ion process and the second ion process.

3. The method of claim 1, wherein the material layer is formed along one or more sidewalls defining each of the plurality of openings.

4. The method of claim 1, wherein the angled ion etch removes the masking material layer at a first end or a second end of the plurality of openings.

5. The method of claim 4, wherein removing the masking material layer at the first end or the second end of the plurality of openings causes a pair of adjacent openings of the plurality of openings to merge together.

6. The method of claim 1, wherein the masking material layer is a resist, and wherein the plurality of openings are vias formed selective to an upper surface of the stack of layers.

7. The method of claim 6, wherein the resist is an extreme ultraviolet resist or a deep ultraviolet resist.

8. The method of claim 1, wherein the material layer is further formed along an upper surface of the masking material layer.

9. A method of modifying a plurality of openings of a resist, the method comprising:
providing a plurality of openings in the resist; and
performing one or more ion processes on the resist to enlarge or reduce one or more dimensions of the plurality of openings, wherein a first ion process of the one or more ion processes comprises directionally depositing a material layer on the resist by directing a material beam at a first non-zero angle relative to a normal direction extending from a top surface of the resist, and wherein a second ion process of the one or more ion processes comprises performing an angled ion etch by delivering an ion beam at a second non-zero angle relative to the normal direction extending from the top surface of the resist.

10. The method of claim 9, further comprising simultaneously performing the first ion process and the second ion process.

11. The method of claim 9, wherein the material layer is formed along one or more sidewalls defining each of the plurality of openings.

12. The method of claim 9, wherein the angled ion etch removes the resist at a first end or a second end of the plurality of openings.

13. The method of claim 12, wherein removing the resist at the first end or the second end of the plurality of openings causes a pair of adjacent openings of the plurality of openings to merge together.

14. The method of claim 9, wherein the resist is an extreme ultraviolet resist or a deep ultraviolet resist, wherein the plurality of openings are vias formed selective to an upper surface of a stack of layers, and wherein the resist is formed atop the stack of layers.

15. A processing apparatus, comprising:
a chamber operable to contain a plasma within a chamber volume; and
a plate assembly proximate the chamber, wherein ions are extracted through a plurality of apertures of the plate assembly and delivered to a semiconductor device as one or more ion processes to enlarge or reduce one or more dimensions of a plurality of openings of a masking material layer formed over a stack of layers, wherein a first ion process of the one or more ion processes comprises directionally depositing a material layer on the masking material layer by directing a material beam at a first non-zero angle relative to a normal direction extending from a top surface of the masking material layer, and wherein a second ion process of the one or more ion processes comprises performing an angled ion etch by delivering an ion beam at a second non-zero angle relative to the normal direction extending from the top surface of the masking material layer.

16. The processing apparatus of claim 15, wherein the first ion process and the second ion process are performed simultaneously.

17. The processing apparatus of claim 15, wherein the material layer is formed along one or more sidewalls defining each of the plurality of openings.

18. The processing apparatus of claim 15, wherein the angled ion etch removes the masking material layer at a first end or a second end of the plurality of openings.

19. The processing apparatus of claim 18, wherein removing the masking material layer at the first end or the second end of the plurality of openings causes a pair of adjacent openings of the plurality of openings to merge together.

20. The processing apparatus of claim 15, wherein the masking material layer is a resist, and wherein the plurality of openings are vias formed selective to an upper surface of the stack of layers, and wherein the one or more ion processes are prevented from impacting the upper surface of the stack of layers.
